(19) United States
(12) Patent Application Publication
(10) Pub. No.: US 2004/0140482 A1
(43) Pub. Date: Jul. 22, 2004

(54) Semiconductor device and process for producing semiconductor device

(75) Inventors: Kazuyuki Kuwada, Ibaraki-shi (JP); Kazuki Uwada, Ibaraki-shi (JP); Yuji Hotta, Ibaraki-shi (JP); Akiko Matsumura, Ibaraki-shi (JP)

Correspondence Address: SUGHRUE MION, PLLC, 2100 PENNSYLVANIA AVENUE, N.W., SUITE 800, WASHINGTON, DC, 20037, US

(73) Assignee: NITTO DENKO CORPORATION

(21) Appl. No.: 10/752,700

(22) Filed: Jan. 8, 2004

(30) Foreign Application Priority Data
Jan. 14, 2003 (JP) P. 2003-005551

(51) Int. Cl. H01L 31/0336

(52) U.S. Cl. 257/200

(57) ABSTRACT

A semiconductor device which comprises a substrate and a semiconductor element mounted thereon through bumps by the so-called flip chip method, and in which the semiconductor element has been encapsulated more easily and with higher certainty. A semiconductor device comprising a substrate and a semiconductor element mounted thereon through bumps, wherein the semiconductor element has been encapsulated by coating the back and the edges of the semiconductor element with a thermosetting sheet material having tackiness. Preferably, the tackiness of the sheet material as measured at time of use is from 2 to 15 in terms of ball tack.

### FIELD OF THE INVENTION

The present invention relates to a semiconductor device and a process for producing the same.

### BACKGROUND OF THE INVENTION

For the purpose of attaining further performance improvements in semiconductor devices, the techniques for connecting a semiconductor element (hereinafter referred to also as “chip”) to a lead frame are recently shifting from the wire bonding method heretofore in use, in which gold wires are used for the connection, to wire-less bonding methods in which no wires are used. Typical examples thereof include the flip chip method in which a semiconductor element having bumps formed on the circuit-bearing side thereof is connected facedown to a substrate, e.g., a mother board, which has a wiring circuit formed.

In the flip chip method, a technique is frequently employed in which a liquid resin or sheet-form resin is usually used as an underfill material between the circuit-bearing side of the chip and the substrate and the chip bonding part is sealed with the underfill material. However, for protecting the back (non-circuit side) and the edges of the chip, for example, a method in which these chip surfaces are coated with a liquid resin or covered by over-molding by transfer molding (Document 1) is used.

Document 1: JP-A-2002-348438

### SUMMARY OF THE INVENTION

However, the method in which chip surfaces are coated with a liquid resin has a problem that the corner edge parts of the chip back are apt to be incompletely coated and remain exposed.

On the other hand, the transfer molding has a problem that it necessitates a complicated large-scale apparatus for heating and melting a resin, injecting the melt into a mold, and molding and curing it in a high-temperature highly pressurized state and, hence, the selection of conditions is troublesome.

The semiconductor device including a flip chip mounted by face down bonding has an advantage that the thickness of the semiconductor device itself can be reduced. However, the back and the edges of the chip cannot be effectively sealed by the encapsulation method using a liquid resin.

In particular, in semiconductor devices having two or more stacked layers of the flip chip, there is a problem that semiconductor elements disposed close to each other should be insulated from each other while attaining a thickness reduction in the semiconductor devices as described above.

Accordingly, an object of the invention is to encapsulate a semiconductor element without fail and to simplify the encapsulation step.

In order to eliminate the problems described above, the invention provides a semiconductor device which comprises a substrate and a semiconductor element mounted thereon through a bump bonding part, wherein the semiconductor element has been encapsulated by coating the back and the edges of the semiconductor element with a thermosetting sheet material having tackiness.

Since the back and the edges of the semiconductor element have been coated with a sheet material, the semiconductor element has a satisfactory encapsulated state. This semiconductor device hence has high reliability.

The invention further provides a process for producing a semiconductor device which comprises encapsulating a semiconductor element mounted on a substrate through a bump bonding part, wherein the semiconductor element is encapsulated by coating the back and the edges of the semiconductor element with a thermosetting sheet material having tackiness.

According to this process for semiconductor device production, steps for semiconductor device production can be simplified because the sheet material can be more easily handled than liquid resins and this process is free from the troublesomeness of selection of conditions as in over-molding.

In the process for semiconductor device production of the invention, the tackiness of the sheet material as measured at time of use is preferably from 2 to 15 in terms of ball tack.

When the sheet material to be used has a tackiness of from 2 to 15 in terms of ball tack, this sheet material can be easily handled and, despite this, can be easily bonded provisionally to a semiconductor element. In addition, when this sheet material is press-bonded to the semiconductor element and substrate, a satisfactory adherent state is attained. Consequently, the semiconductor element can be encapsulated in a void-free state without fail.

A preferred embodiment of the process for semiconductor device production of the invention described above comprises covering the back of the semiconductor element with the sheet material having an area larger than the back of the semiconductor element, press-bonding the sheet material to thereby coat the back and the edges of the semiconductor element with the sheet material, and then thermally curing the sheet material to thereby encapsulate the semiconductor element.

According to this process, the back and the edges of the semiconductor element can be simultaneously sealed with the sheet material having an area larger than the back of the semiconductor element. In addition, upon press-bonding, the sheet material can conform to the shape of the semiconductor element and encapsulate it without leaving a space between them.

### DETAILED DESCRIPTION OF THE INVENTION

The present invention will be explained below in detail.

The semiconductor device of the invention comprises a substrate and a semiconductor element mounted thereon through a bump bonding part, wherein the semiconductor element has been encapsulated by coating the back and the edges of the semiconductor element with a thermosetting sheet material having tackiness.

As the thermosetting sheet material is used a film made of a thermosetting resin which has tackiness at time of use. Suitable for use as the thermosetting resin is a rubber-containing or rubber-modified polycarbodiimide resin. This is because this resin has excellent film-forming properties and has satisfactory tackiness at room temperature.

In case where tackiness is imparted to a thermosetting resin by merely adding a rubber alone, not only the dispersion stability can be insufficient, but also there is a possibility that the strength required after film formation for peeling from the substrate and the adhesion strength after encapsulation might fluctuate. It is therefore preferred to utilize a reactive liquid rubber having functional groups. Examples of this reactive liquid rubber include liquid polybutadiene, liquid polybutadiene-acrylonitrile copolymers, liquid polyisoprene, liquid hydrogenated polyisoprene, and modifications thereof.

The tackiness of the sheet material is preferably 2 or higher, more preferably 4 or higher, in terms of ball tack. Furthermore, the ball tack thereof is preferably 15 or lower, more preferably 10 or lower. In case where the ball tack of the sheet material is 2 or more, it is possible to avoid that the sheet material has poor tackiness and avoid a possibility that the sheet material might come into a poorly adherent state after application to the back side and edges of a mounted flip chip, etc. to cause voids. In case where the ball tack thereof is 15 or less, it is possible to avoid that the sheet material has excessive tackiness and avoid a possibility that the operation for applying the sheet material cannot be performed smoothly.

The term “ball tack” in the invention means values obtained by the ball rolling method as provided for in JIS Z 0237.

For obtaining such tackiness, it is preferred to add the reactive liquid rubber in an amount in the range of from 50 to 500 parts by weight per 100 parts by weight of the thermosetting resin. In case where the amount of the reactive liquid rubber added is 50 parts by weight or more, it is possible to avoid a possibility that sufficient tackiness cannot be obtained at room temperature. Conversely, in case where the amount thereof is 500 parts by weight or smaller, it is possible to avoid a possibility of excessive tackiness.

A fine inorganic filler may be incorporated into the thermosetting resin according to need as long as this incorporation does not impair processability and heat resistance. The amount of the inorganic filler to be incorporated is generally from 0 to 75 parts by weight, preferably from 0 to 50 parts by weight, per 100 parts by weight of the thermosetting resin into which a reactive liquid rubber has been incorporated.

For the purpose of improving adhesion strength after cure, various additives such as, e.g., a silane coupling agent, titanate coupling agent, fluorochemical surfactant, and silicone additive may be added to the sheet material according to need.

It is also possible to color the material, e.g., by incorporating carbon for coloration as in the case of ordinary black plastic encapsulation materials.

The sheet material to be used in the invention can be obtained by forming the thermosetting resin into a film having a thickness of, for example, from 10 to 500 μm on a heat-resistant substrate.

For this film formation, an ordinary process for film production can be utilized. For example, the thermosetting resin is dissolved in a ketone solvent such as acetone, methyl ethyl ketone, or cyclohexanone, a cyclic ether solvent such as tetrahydrofuran or dioxane, or an aromatic hydrocarbon solvent such as toluene or xylene to prepare a resin solution. This resin solution is applied by a known technique such as, e.g., casting or roll coating. Thus, a film of the resin can be formed.

Such solvents may be used alone or as a mixture of two or more thereof.

The thickness of the sheet material can be suitably changed in the range of from 10 to 500 μm according to the thickness of the chip to be encapsulated, height of the bump bonding part, etc. However, the thickness of the sheet material for a general one-layer chip is preferably from 10 to 300 μm, and that for stacked chips arranged in two or more layers is preferably from 50 to 500 μm.

In case where the thickness of the sheet material is the above-described lower limit or higher, it is possible to avoid that the resin amount becomes insufficient for encapsulation and it is possible to completely coat and seal the back and corner edge parts of the chip. In case where the thickness thereof is the above-described upper limit or lower, it is possible to avoid that the resin amount becomes excessively large and the resin disposed on the chip back has too large a thickness, so that it is possible to attain a reduction in semiconductor device thickness.

The process for semiconductor device production in which the thermosetting sheet material having tackiness obtained in the manner described above is used to encapsulate a flip chip mounted on a substrate will be explained next.

First, the sheet material is cut into a size having a larger area than the chip to be sealed. This cut sheet material is put on the back of the flip chip mounted on a substrate. The size of this sheet material is preferably such that each edge is longer by about from 2 to 5 mm than the corresponding edge of the chip. In the case where two or more chips have been mounted in respective positions on the same substrate, it is preferred to use a sheet material having a size sufficient to simultaneously cover these chips.

Thereafter, the sheet material is provisionally bonded to the flip chip with a pressure roll or the like. Specifically, the sheet material is press-bonded to the flip chip with the pressure roll to thereby coat the back and the edges of the flip chip and simultaneously seal the periphery of the bump bonding part. This step may usually be conducted at room temperature (23°), it may be conducted at a temperature in the range of from 15 to 150° C. according to the tackiness of the sheet material and other conditions. Temperatures of 15° C. or higher are desirable in order to avoid a possibility that the sheet material itself might be deprived of tackiness. Temperatures of 150° C. or lower are desirable in order to avoid a possibility that curing of the resin might proceed. Thus, the above-described temperature range is preferable for the operation of provisional bonding.

The resultant semiconductor device having the sheet material provisionally bonded thereto is heat-treated to cure the resin constituting the sheet material and thereby sufficiently bond the sheet material to the back and edges of the chip and to the substrate. Thus, the back and edges of the flip chip and the bump bonding part are completely sealed with the sheet material.

The invention will be explained below in more detail by reference to Examples and Comparative Example.

### PRODUCTION EXAMPLE 1

Into a 500-mL four-necked flask equipped with a stirrer, dropping funnel, reflux condenser, and thermometer were introduced 10.5 g (60 mmol) of tolylene diisocyanate (isomer mixture; Takenate 80, manufactured by Mitsui-Takeda Chemical), 15.0 g (60 mmol) of naphthalene diisocyanate, 86.1 g of a liquid polybutadiene-acrylonitrile copolymer (Hycar-CTBN1300X13, manufactured by B. F. Goodrich), and 232 g of toluene. These ingredients were mixed together. This mixture was stirred at 50° C. for 1 hour. Thereto were added 8.32 g (49.2 mmol) of 1-naphthyl isocyanate and 0.46 g (2.4 mmol) of 3-methyl-1-phenyl-2-phospholene 2-oxide. The resultant mixture was heated to 100° C. with stirring and then held for further 2 hours. The progress of reactions was ascertained by infrared spectroscopy (FT/IR-230, manufactured by JEOL Ltd.). Specifically, the decrease in the amount of absorption by N—C—O stretching vibration attributable to the isocyanates (2,270 cm⁻¹), the increase in the amount of absorption by N—C—N stretching vibration attributable to carbodiimide (2,135 cm⁻¹), and the increase in the amount of absorption by C—O stretching vibration attributable to the C—O in each linking amide group (1,695 cm⁻¹) were followed to thereby ascertain the progress and end point of each reaction. Thereafter, the reaction mixture was cooled to room temperature. Thus, a polycarbodiimide solution was obtained.

### EXAMPLE 1

The polycarbodiimide solution was applied to a separator (thickness, 50 μm) consisting of a poly(ethylene terephthalate) film treated with a release agent. The coating was heated at 130° C. for 1 minute and then heated at 150° C. for 1 minute to obtain a tacky thermosetting sheet material (thickness, 150 μm). The tackiness of this sheet material as measured at room temperature was 7 in terms of ball tack.

Subsequently, the sheet material was cut into a size of 9 mm×9 mm. This cut sheet material was put on a flip chip (chip size, 5 mm×5 mm×70 μm; ball bond height, 80 μm; with underfill material) mounted on a substrate. Provisional bonding was conducted with a roll at room temperature.

Thereafter, the sheet material applied was heated at 175° C. for 5 hours to cure the resin. Thus, chip encapsulation was completed.

### EXAMPLE 2

The polycarbodiimide solution was applied to a separator (thickness, 50 μm) consisting of a poly(ethylene terephthalate) film treated with a release agent. The coating was heated at 130° C. for 1 minute and then heated at 150° C. for 2 minutes to obtain a tacky thermosetting sheet material (thickness, 200 μm). The tackiness of this sheet material as measured at room temperature was 4 in terms of ball tack.

Subsequently, the sheet material was cut into a size of 9 mm×9 mm. This cut sheet material was put on flip chips (chip size, 5 mm×5 mm×70 μm; ball bond height, 80 μm; with underfill material) mounted in two-layer arrangement on a substrate. Provisional bonding was conducted with a roll at room temperature.

Ther after, the sheet material applied was heated at 175° C. for 5 hours to cure the resin. Thus, chip encapsulation was completed.

### EXAMPLE 3

The polycarbodiimide solution was used to obtain a tacky thermosetting sheet material in the same manner as in Example 1, except that the thickness thereof was changed to 250 μm. This sheet material also had a thickness as measured at room temperature of 7 in terms of ball tack.

Subsequently, the sheet material was cut into a size of 9 mm×9 mm. This cut sheet material was put on flip chips (chip size, 5 mm×5 mm×50 μm; ball bond height, 70 μm; with underfill material) mounted in two-layer arrangement on a substrate. Provisional bonding was conducted with a roll at room temperature.

Thereafter, the sheet material applied was heated at 175° C. for 5 hours to cure the resin. Thus, chip encapsulation was completed.

### COMPARATIVE EXAMPLE 1

A thermosetting sheet was obtained in the same manner as in Example 1, except that the polycarbodiimide solution used was one which did not contain the liquid polybutadiene-acrylonitrile copolymer. This sheet material had no tackiness at room temperature and the ball tack thereof was below 2. This thermosetting sheet material was used to encapsulate a chip in the same manner as in Example 1.

Evaluation 1

With respect to each of the semiconductor devices obtained in Examples 1 to 3, five samples were cut and the sealed state of the back and edges of each chip was examined with a microscope. As a result, no void was observed in each of Examples 1 to 3.

In contrast, in Comparative Example 1, voids were observed in edge parts of each chip. It was thus found that the sealing was incomplete.

Evaluation 2

The semiconductor devices obtained in Examples 1 to 3 were subjected to a TCT (temperature cycle test; −25° C.×30 min/150° C.×30 min; 500 cycles). Thereafter, they were immersed in a red flaw detection liquid and examined for separation between the resin (cured sheet material) and the substrate. As a result, no separation was observed in each of Examples 1 to 3.

In contrast, in Comparative Example 1, the chip edge parts in which voids had been observed were found to have developed minute cracks.

As described above, according to the semiconductor device and process for producing the same of the invention, it is possible to easily encapsulate, without fail, a flip chip mounted by face down bonding, while enabling the semiconductor device including this semiconductor element to have a reduced thickness.

While the invention has been described in detail and with reference to specific embodiments thereof, it will be apparent to one skilled in the art that various changes and modifications can be made therein without departing from the scope thereof.

This application is based on Japanese patent application No. 2003-005551 filed Jan. 14, 2003, the entire contents thereof being hereby incorporated by reference.

What is claimed is:

1. A semiconductor device which comprises a substrate and a semiconductor element mounted thereon through a bump bonding part, wherein
the semiconductor element has been encapsulated by coating the back and the edges of the semiconductor element with a thermosetting sheet material having tackiness.

2. A process for producing a semiconductor device which comprises a substrate and a semiconductor element mounted thereon through a bump bonding part, which comprises encapsulating the semiconductor element by coating the back and the edges of the semiconductor element with a thermosetting sheet material having tackiness.

3. The process for producing a semiconductor device of claim 2, wherein the tackiness of the sheet material as measured at time of use is from 2 to 15 in terms of ball tack.

4. The process for producing a semiconductor device of claim 2, which comprises covering the back of the semiconductor element with the sheet material having an area larger than the back of the semiconductor element, press-bonding the sheet material to thereby coat the back and the edges of the semiconductor element with the sheet material, and then thermally curing the sheet material to thereby encapsulate the semiconductor element.

5. The process for producing a semiconductor device of claim 3, which comprises covering the back of the semiconductor element with the sheet material having an area larger than the back of the semiconductor element, press-bonding the sheet material to thereby coat the back and the edges of the semiconductor element with the sheet material, and then thermally curing the sheet material to thereby encapsulate the semiconductor element.
